(19) United States
(12) Patent Application Publication
(10) Pub. No.: US 2026/0324160 A1
(43) Pub. Date: Oct. 15, 2026

(54) OPTOELECTRONIC SEMICONDUCTOR DEVICE, OPTOELECTRONIC COMPONENT AND METHOD FOR OPERATING AN OPTOELECTRONIC COMPONENT

(71) Applicant: ams-OSRAM International GmbH, Regensburg (DE)

(72) Inventors: Norwin von Malm, Nittendorf (DE); Adrian Stefan Avramescu, Regensburg (DE); Martin Hetzl, Painten (DE); Anna Kasprzak-Zablocka, Donaustauf (DE)

(21) Appl. No.: 19/473,865

(22) PCT Filed: Apr. 4, 2024
(86) PCT No.: PCT/EP2024/059190

§ 371 Date: Oct. 9, 2025

(30) Foreign Application Priority Data
Apr. 12, 2023 (DE) 10 2023 109 197.2

(51) Int. Cl. H10H 29/80; H10H 20/819; H10H 20/824; H10H 29/14; H10H 29/855

(52) U.S. Cl. CPC H10H 29/8321; H10H 20/819; H10H 20/824; H10H 29/14; H10H 29/842; H10H 29/855

(57) ABSTRACT

In an embodiment an optoelectronic semiconductor device includes a p-type semiconductor layer, an n-type semiconductor layer, an active region arranged between the p-type semiconductor layer and the n-type semiconductor layer, a p-contact contacting at most 50% of an area of the p-type semiconductor layer, and an n-contact arranged on a side of the n-type semiconductor layer facing away from the p-type semiconductor layer, wherein the p-contact is arranged on a side of the p-type semiconductor layer facing away from the active region.

### CROSS-REFERENCE TO RELATED APPLICATIONS

This patent application is a national phase filing under section 371 of PCT/EP2024/059190, filed Apr. 4, 2024, which claims the priority of German patent application no. 102023109197.2, filed Apr. 12, 2023, each of which is incorporated herein by reference in its entirety.

### TECHNICAL FIELD

The present disclosure relates to an optoelectronic semiconductor device, an optoelectronic component comprising an optoelectronic semiconductor device and to a method for operating an optoelectronic component.

### SUMMARY

Embodiments provide an optoelectronic semiconductor device that can be operated efficiently. In particular, embodiments provide an optoelectronic semiconductor device with an improved efficiency for optical data communication applications.

Further embodiments provide an optoelectronic component comprising an optoelectronic semiconductor device that can be operated efficiently. Yet other embodiments provide a method for efficiently operating an optoelectronic component.

According to at least one aspect of the optoelectronic semiconductor device, the optoelectronic semiconductor device comprises a p-type semiconductor layer. The p-type semiconductor layer can comprise a semiconductor material which can be p-doped. For example, the p-type semiconductor layer comprises a III-V semiconductor material or is formed of a III-V semiconductor material. The p-type semiconductor layer can be formed of a single layer or can comprise a layer sequence.

According to at least one aspect, the optoelectronic semiconductor device comprises an n-type semiconductor layer. The n-type semiconductor layer can comprise a semiconductor material which can be n-doped. For example, the n-type semiconductor layer comprises a III-V semiconductor material or is formed of a III-V semiconductor material. The n-type semiconductor layer can be formed of a single layer or of a layer sequence.

According to at least one aspect, the optoelectronic semiconductor device comprises an active region, which is arranged between the p-type semiconductor layer and the n-type semiconductor layer.

The active region can be configured to generate electromagnetic radiation. The electromagnetic radiation generated by the active region in particular can comprise light. For example, the electromagnetic radiation generated by the active region can comprise visible light, UV light and/or infrared light. The active region can comprise a pn-junction, a quantum well and/or a multi-quantum well, for example. The electromagnetic radiation generated by the active region can be an optical signal for optical data communication applications.

Alternatively, the optoelectronic semiconductor device and the active region of the optoelectronic semiconductor device can be configured for the detection of electromagnetic radiation.

The active region can be arranged directly between the p-type semiconductor layer and the n-type semiconductor layer. The active region, the n-type semiconductor layer and the p-type semiconductor layer can form at least a part of a semiconductor layer sequence of the optoelectronic semiconductor device. For example, along a stacking direction of the semiconductor layer sequence the p-type semiconductor layer, the active region and the n-type semiconductor layer sequence are arranged one after the other, for example directly one after the other. A thickness of the semiconductor layer sequence can be at most 5 μm, for example at most 2 μm or for example at most 1 μm.

The active region, the p-type semiconductor layer and/or the n-type semiconductor layer comprise a main extension plane. The main extension plane of the active region, the p-type semiconductor layer and/or the n-type semiconductor layer can at least approximately be perpendicular to the stacking direction of the semiconductor layer sequence.

According to at least one aspect, the optoelectronic semiconductor device comprises a p-contact. For example, the p-contact is directly adjacent to the p-type semiconductor layer.

The p-contact can be arranged on a side of the p-type semiconductor layer facing away from the active region. The p-contact can contact the p-type semiconductor layer. For example, the p-contact is arranged on an outer surface of the p-type semiconductor layer. The p-contact can comprise or can be formed of a metal and/or a transparent conductive oxide (TCO). The p-contact can be configured to electrically contact the p-type semiconductor layer. In particular, the p-contact can be the only component of the optoelectronic semiconductor device electrically contacting the p-type semiconductor layer. In other words, current can only be injected into the p-type semiconductor layer by the p-contact. This can mean that the semiconductor device is free of a current spreading layer. For instance, no current spreading layer is arranged between the p-contact and the p-type semiconductor layer.

The p-contact can be configured as a mirror. This can mean, that the p-contact is reflective for the electromagnetic radiation generated by or detected in the active region. Thus, electromagnetic radiation impinging on the p-contact can be reflected and be directed towards the n-type semiconductor layer and/or towards a light out-coupling area of the optoelectronic semiconductor device. The reflectivity of the p-contact can be at least 50%, for example at least 80% or for example at least 90% for the electromagnetic radiation generated by the active region.

According to at least one aspect of the optoelectronic semiconductor device, the p-contact contacts at most 50% of an area of the p-type semiconductor layer.

That the p-contact contacts at most 50% of an area of the p-type semiconductor layer can mean that the p-contact is directly adjacent to the p-type semiconductor layer on at most 50% of the area of the p-type semiconductor layer. In other words, the p-contact and the p-type semiconductor layer can comprise a common interface, which extends at most 50% over the side of the p-type semiconductor layer facing the p-contact.

It can also mean that the p-contact is configured to electrically contact at most 50% of the area of the p-type semiconductor layer. The area of the p-type semiconductor layer can be the area of the p-type semiconductor layer facing the p-contact. For example, the area of the p-type semiconductor layer can correspond to the area of the p-type semiconductor layer along the main extension plane of the p-type semiconductor layer. The p-contact for example can contact at most 25% of the area of the p-type semiconductor layer. For example, the p-contact contacts at most 20%, for example at most 15% or, in particular, at most 10% of the area of the p-type semiconductor layer.

The current injected by the p-contact into the p-type semiconductor layer can laterally spread inside the p-type semiconductor layer. Thereby, laterally can refer to a direction extending perpendicular to a stacking direction of the semiconductor layers in the semiconductor layer sequence.

It is possible, that the p-contact of the optoelectronic semiconductor device comprises exactly one part. Further, it is possible that the p-contact is divided in two or more parts. The totality of the parts of the p-contact then forms the p-contact. For example, the totality of the parts of the p-contact contacts at most 50% of the p-type semiconductor layer. The parts of the p-contact can be connected with each other.

According to at least one aspect, the optoelectronic semiconductor device comprises a p-type semiconductor layer, an n-type semiconductor layer, an active region, which is arranged between the p-type semiconductor layer and the n-type semiconductor layer, and a p-contact, wherein the p-contact contacts at most 50% of an area of the p-type semiconductor layer.

For example the use of LEDs, e.g. micro-LEDs, in optical data communication applications can be advantageous over VCSEL technology. LEDs can provide a better scalability and a lower current operation, while maintaining high current density and thus, can be operated energy efficient. The application of LEDs in optical data communication can be limited due to a radiative lifetime, limiting the rise and fall times of light emission of LEDs when modulating or turning on/off the LED, for example.

The radiative lifetime can be decreased by background doping to increase the charge carrier density for certain charge carrier types. Alternatively, the material quality might be decreased or non-radiative defect centres for non-radiative recombination might be implemented within the active region to decrease a charge carrier lifetime.

The above mentioned approaches disadvantageously reduce the efficiency of the micro-LED and induce reliability issues. Further, they are hardly controllable and reproducible.

The optoelectronic semiconductor device described herein has, amongst others, the advantage that it can be operated efficiently. For example, the optoelectronic semiconductor device has an enhanced efficiency for optical data communication applications. The efficiency can be improved by providing small and/or multiple pixelated contacts, for example. By applying pixelated contacts or small contacts, especially a pixelated or small p-contact, the current injection can be limited to small or very small areas. This can be achieved by forming the p-contact to contact at most 50%, for example at most 30% or at most 10% of the p-type semiconductor layer of the optoelectronic semiconductor device. Contacting the p-type semiconductor layer only in small areas can lead to a locally high current density in the p-type semiconductor layer. A higher current density can enable an improved switching speed of the optoelectronic semiconductor device, for example.

A further advantage of the optoelectronic semiconductor device described herein is that due to the small p-contact and/or pixelated p-contacts, for example, due to the p-contact, contacting at most 50% of an area of the p-type semiconductor layer, a distance between the recombination zone and the chip's circumference can be increased, leading to less non-radiative recombination, which in turn leads to an enhanced efficiency of the optoelectronic semiconductor device.

The optoelectronic semiconductor device described herein can be operated energy efficient in optical data communication technology. A further advantage of the optoelectronic semiconductor device described herein is that it can be operated by a low current, for example in comparison to a laser, e.g. a vertical-cavity surface-emitting laser (VCSEL). Additionally, the optoelectronic semiconductor device can have a good scalability. This can mean, that it can be easily formed in different sizes. This can be achieved by forming the optoelectronic semiconductor device with a plurality of pixels or by assembling optoelectronic semiconductor devices to a dense array, for example.

According to at least one aspect of the optoelectronic semiconductor device, the p-contact contacts at most 25%, in particular at most 10%, of the p-type semiconductor layer. The p-contact can contact at most 25%, at most 20%, for example at most 15% or, in particular, at most 10% of the p-type semiconductor layer. Current can be injected into the p-type semiconductor layer via the p-contact. For example, current is injected into the p-type semiconductor layer only via the p-contact. The p-type semiconductor layer can comprise a non-uniform current distribution. For example, the p-type semiconductor layer can have a high current density in regions close to the p-contact. That the current density is high in these regions can mean, that the current density is larger than in other regions of the p-type semiconductor layer.

Due to a smaller p-contact, the area of the p-type semiconductor layer in which current is injected into the p-type semiconductor layer can be decreased. This can lead to a locally high current density which can lead to an improved switching speed of the optoelectronic semiconductor device, for example.

According to at least one aspect, the p-type semiconductor layer, the n-type semiconductor layer and/or the active layer are based on a III-V semiconductor material, in particular on AlInGaP, GaInN and/or AlInGaAs. Alternatively, it is also possible, that the semiconductor layer sequence comprising the p-type semiconductor layer, the n-type semiconductor layer and the active layer is based on a II-VI semiconductor material.

According to at least one aspect, the optoelectronic semiconductor device further comprises an insulating layer, wherein the insulating layer is directly adjacent to the p-type semiconductor layer on a side of the p-type semiconductor layer facing away from the active region, and an interface between the p-contact and the p-type semiconductor layer is smaller than an interface between the insulating layer and the p-type semiconductor layer. The insulating layer can comprise an insulating material. For example, the insulating layer can comprise a dielectric material and/or SiO₂. The side of the p-type semiconductor layer facing away from the active region can be completely covered directly by the p-contact and the insulating layer. This can in particular mean, that regions of the side of the p-type semiconductor layer, which are not in direct contact with the p-contact, are in direct contact with the insulating layer. For example, also the side surfaces of the p-type semiconductor layer and/or the side surfaces of the semiconductor layer sequence are directly adjacent to the insulating layer. The side surfaces can, for example, extend at least approximately in parallel to the stacking direction of the semiconductor layer sequence. This can mean, that the p-contact can be the only electrically conductive layer being directly adjacent to the p-type semiconductor layer sequence.

According to at least one aspect, the optoelectronic semiconductor device comprises an optical separation. The optical separation can comprise an optically opaque material. For example, the optical separation comprises an electrically insulating material, in particular a material of the insulating layer. The optical separation can be directly adjacent to the insulating layer or can be integrally formed with the insulating layer.

It is also possible, that the optical separation can be electrically conductive and/or comprise an electrically conductive material.

The optical separation e.g. can be reflective for the electromagnetic radiation produced or detected in the active region.

The optical separation is arranged at least in the active region. For example, the optical separation extends through the active region and/or the p-type semiconductor layer. The optical separation can also extend into the n-type semiconductor layer. For example, the optical separation extends completely through the semiconductor layer sequence of the optoelectronic semiconductor device.

The optical separation can be formed as a separating wall. For example, the optical separation is formed of separating walls arranged in a grid-like manner. Thereby, the optical separation can be arranged between pixels of the optoelectronic semiconductor device. It is also possible, that each separating wall circularly surrounds a pixel or defines a pixel. The pixels can comprise a common and/or continuous active region or arise from a common active zone. Alternatively or additionally, the optical separation can circularly surround the p-contact. For example, each p-contact is circularly surrounded by an optical separation.

Due to the optical separation, optical cross-talk between pixels of the optoelectronic semiconductor device can be reduced or prevented.

According to at least one aspect, the at least one p-contact is spaced apart from an n-contact by a separation region in a lateral direction, wherein the p-contact does not overlap the n-contact.

This can mean that in top view of the optoelectronic semiconductor device the p-contact and the n-contact do not overlap. In other words, the p-contact can, for example, not exceed the separation region in the lateral direction. The separation region can be arranged between the n-contact layer and the p-contact. For example, the n-contact can comprise an n-contact layer and an n-contact via. The p-contact can be formed as a through contact, which can be laterally completely surrounded by the n-contact at least partially. In this case, the n-contact and the p-contact can be arranged on the same side of the semiconductor layer sequence, for example on the p-side.

Each pixel of the optoelectronic semiconductor device can comprise one n-contact. Alternatively, it is possible, that the n-contacts are distributed over the optoelectronic semiconductor device and/or are not each assigned to only one pixel.

The n-contact can be configured as a mirror. In other words, the n-contact can be reflective for the electromagnetic radiation generated by or detected in the active region of the optoelectronic semiconductor device. Thus, electromagnetic radiation impinging on the n-contact layer can be reflected and be directed towards the n-type semiconductor layer and/or towards the light out-coupling area of the optoelectronic semiconductor device. The reflectivity of the n-contact layer can be at least 50%, for example at least 80% or for example at least 90% for the electromagnetic radiation generated by the active region.

According to one aspect of the optoelectronic semiconductor device, the n-contact of the device comprises an n-contact layer which is arranged over the entire surface of the optoelectronic semiconductor device below the p-contact wherein, in top view, the p-contact is laterally surrounded by the n-contact layer. In particular, the n-contact layer can be arranged below parts of the p-contact. This can mean that the p-contact can protrude the n-contact layer towards the p-type semiconductor layer. For example, in this embodiment the n-contact layer is arranged below the insulating layer over the entire surface or nearly the entire surface of the device. Thereby, it is possible that the n-contact layer protrudes laterally at the edge of the semiconductor layers of the device. Such a large surface layer enables good heat dissipation and reflection of electromagnetic radiation. Further, the p-contact can be let through this n-contact layer and consequently the p-contact is laterally surrounded by the n-contact layer in top view.

According to at least one aspect of the optoelectronic semiconductor device, the n-contact comprises an n-contact layer and n-contact vias which reach through a plane in which the p-contact is arranged. Thereby, the n-contact vias, for example, reach through the insulating layer, the p-type semiconductor layer and the active region into the n-type semiconductor layer. Thereby the plane in which the p-contact is arranged is, for example, given by the underside of the p-type semiconductor layer which faces away from the active region. With such n-contact vias it is possible to contact the n-contacting semiconductor layer without shadowing or shading on the radiation exit side of the device.

According to one aspect of the optoelectronic semiconductor device, the optoelectronic semiconductor device comprises a plurality of pixels and the number of n-contact vias is smaller than the number of pixels. That is to say, it is not necessary to arrange one or more than one n-contact vias for each pixel of the device but it is, for example, sufficient to arrange n-contact vias in every second or third pixel of the device. In this way, particularly small areas of the active region are destroyed by forming the n-contact vias. Further, high current densities are enabled by the small area of the p-contact which allows for high switching speeds. Further, the edge of the device is relatively far from the recombination zone, which is located at the p-contact, resulting in a higher efficiency of the device.

According to one aspect of the optoelectronic semiconductor device, the n-contact is formed along a side surface of the semiconductor layers to a side of the n-side semiconductor layer which faces away from the active region. There, the n-type semiconductor layer is covered by the n-contact in the shape of a contact grip. According to this aspect it is not necessary to arrange n-contact vias through the active region, but the n-contact is formed at the edge of the device, for example in direct contact with the insulating layer from the underside of the device to the top side of the device. At the top side of the device, a contact grid is formed by the n-contact material. This allows for a particularly easy and cost-effective production of the device, but parts of the radiation exit side of the device are covered and therefore shaded by the contact grid.

According to at least one aspect, the optoelectronic semiconductor device comprises a plurality of pixels. Each pixel can provide a region of the optoelectronic semiconductor device, from which electromagnetic radiation is coupled out of the optoelectronic semiconductor device. The pixels can emit electromagnetic radiation having the same or different wavelengths. Thus, electromagnetic radiation can be emitted at a plurality of defined positions, for example the pixels, of the optoelectronic semiconductor device. The pixels can have a lateral extension, for example in a direction substantially parallel to the main extension direction of the semiconductor layer sequence, of at most 100 μm, for example at most 70 μm or for example at most 40 μm.

Each pixel can comprise a p-contact, for example exactly one p-contact. That each pixel can comprise exactly one p-contact can mean that the p-contact of the pixel contacts at most 50%, at most 30% or at most 10% of an area of the p-type semiconductor layer of the pixel, for example. The pixels can be activated separately, for example by activating the corresponding p-contact.

According to at least one aspect of the optoelectronic semiconductor device, at least two pixels of the plurality of pixels comprise a common and continuous active region or arise from a common active zone. Due to this, the optoelectronic semiconductor device can, advantageously, comprise less edges, extending at least approximately parallel to the stacking direction, than an optoelectronic semiconductor device comprising separately formed pixels and/or micro-LEDs. Additionally, the pixels of the optoelectronic semiconductor device according to this aspect can be manufactured efficiently.

According to at least one aspect of the optoelectronic semiconductor device, the n-type semiconductor layer comprises a recess, the recess extends from a side of the n-type semiconductor layer facing away from the active region towards the active region, the recess does not extend into the active region, and the recess is at least partially filled with an insulating material. For example, the recess can be filled completely with an insulating material. The material filling the recess can be transparent, for example transparent for the electromagnetic radiation generated by the active region of the optoelectronic semiconductor device.

The recess can be filled with air, for example. The recess can be arranged within the area of one pixel. This can mean, that the recess is not arranged directly between two pixels. The recess can be completely surrounded by the n-type semiconductor layer of the pixel.

Due to the recess in the n-type semiconductor layer the local current density in the optoelectronic semiconductor device can be increased. This can be achieved by limiting the current spreading inside the n-type semiconductor layer with the recess, for example.

According to at least one aspect, the optoelectronic semiconductor device comprises or is a micro-LED. As a broad definition, a micro-LED could be seen as any light emitting diode (LED)—generally not a laser—with a particularly small size. As a rule—and this is a very important criterion in addition to size—a growth substrate can be removed from micro-LEDs, so that typical heights of such micro-LEDs can be in the range of 1.5 μm to 10 μm, for example.

In principle, a micro-LED does not necessarily have to have a rectangular radiation emission surface. Generally, for example, a micro-LED could have a radiation emission surface in which, in plan view of the layers of the layer stack, any lateral extent of the radiation emission surface is less than or equal to 100 μm or less than or equal to 70 μm. For example, in the case of rectangular micro-LEDs, an edge length-especially in plan view of the layers of the layer stack smaller than or equal to 70 μm or smaller than or equal to 50 μm is often cited as a criterion. Mostly, such micro-LEDs are provided on wafers with-for the μLED non-destructively detachable holding structures. At present, micro-LEDs are mainly used in displays. The micro-LEDs form pixels or subpixels and emit light of a defined color.

Small pixel size and a high density with close distances make micro-LEDs suitable, among others, for small monolithic displays for AR applications, especially data glasses. In addition, other applications are being developed, in particular regarding the use in optical data communication or pixelated lighting applications. Different ways of spelling micro-LED, e.g. μLED, μ-LED, uLED, u-LED or micro light emitting diode can be found in the relevant literature.

For example, the optoelectronic semiconductor device comprises at least one micro-LED. The optoelectronic semiconductor device can comprise an array of micro-LEDs, for example a dense packing of micro-LEDs.

According to at least one aspect of the optoelectronic semiconductor device, the pixels of the optoelectronic semiconductor device are formed by micro-LEDs. The micro-LEDs can be arranged on a carrier, for example on a common carrier. For example, the micro-LEDs are arranged spaced apart from one another. That the pixels are formed by micro-LEDs can in particular mean that the micro-LEDs were formed separately and can afterwards be arranged on a carrier, for example.

According to at least one aspect, the optoelectronic semiconductor device emits electromagnetic radiation and is configured for optical data communication. For example, the electromagnetic radiation emitted by the optoelectronic semiconductor device is modulated and carries information, which can be communicated via an optical fiber. The optoelectronic semiconductor device can comprise a high quantum efficiency and a fast light output modulation to allow for high data rates.

According to at least one aspect, the optoelectronic semiconductor device comprises a carrier. For example, the optoelectronic semiconductor device comprises a plurality of pixels, wherein the plurality of pixels share a common carrier. The carrier can comprise a plurality of switches, wherein each p-contact can be assigned to a switch. For example, the p-contact can be activated using the switch. That the p-contact is active can mean, that current is injected into the p-type semiconductor layer via the p-contact.

Furthermore, an optoelectronic component is provided. The optoelectronic component preferably comprises an optoelectronic semiconductor device described herein. This means all features disclosed for the optoelectronic semiconductor device are also disclosed for the optoelectronic component and vice-versa.

According to at least one aspect of the optoelectronic component, the optoelectronic component comprises an optoelectronic semiconductor device described herein, and further comprises an optical fiber. The optoelectronic semiconductor device is configured to emit electromagnetic radiation and the optical fiber is configured to transfer the electromagnetic radiation emitted by the optoelectronic semiconductor device. For example, the optoelectronic semiconductor device emits the electromagnetic radiation on a side of the optoelectronic semiconductor device facing the optical fiber. Preferably, the electromagnetic radiation can be emitted towards the optical fiber. The electromagnetic radiation can be coupled into the optical fiber, for example.

The optical fiber can comprise a core and a cladding layer. For example, the optical fiber is configured for optical data communication. It is possible, that the electromagnetic radiation emitted by the optoelectronic semiconductor device is transmitted through the optical fiber. For example, the electromagnetic radiation emitted by the optoelectronic semiconductor device is the optical signal transferred with the optical fiber. The optical signal can be guided inside the optical fiber, in particular inside the core of the optical fiber.

The optoelectronic component according to this aspect can efficiently transfer the optical signal provided by the optoelectronic semiconductor device with the optical fiber.

According to at least one aspect of the optoelectronic component, the optical fiber is a multicore fiber, and each pixel of the optoelectronic semiconductor device is assigned one core of the optical fiber. That the optical fiber is a multicore fiber can mean that the optical fiber comprises a plurality of cores. For example, the optical fiber is an imaging fiber.

Thereby, the optoelectronic semiconductor device can comprise at least one pixel. The pixel or each pixel can be assigned one core of the optical fiber. Each pixel can be configured to emit electromagnetic radiation. The electromagnetic radiation, e.g. the optical signal, emitted by the pixel can be coupled into the core assigned to the pixel.

For example, each core of the multicore fiber is assigned to at most one pixel of the optoelectronic semiconductor device.

An advantage of this aspect of the optoelectronic component is that the optical signals emitted by the pixels of the optoelectronic semiconductor device can be efficiently transferred through the optical fiber simultaneously. This can mean, that the optical signals can be transferred through different cores of the optical fiber in parallel.

Furthermore, a method for operating an optoelectronic component is provided. The optoelectronic component described herein can preferably be operated according to the method for operating an optoelectronic component. This means all features disclosed for the optoelectronic component are also disclosed for the method for operating an optoelectronic component and vice-versa.

According to at least one aspect of the method for operating an optoelectronic component, the optoelectronic component is an optoelectronic component described herein and during operation, light emitted by the optoelectronic semiconductor device is coupled into an optical fiber. The optoelectronic component can be configured for optical data communication and can transfer an optical signal, during operation.

According to at least one aspect of the method for operating an optoelectronic component, the optical fiber is a multicore fiber, each pixel of the optoelectronic semiconductor device is assigned a core of the multicore fiber, and the multicore fiber is configured to transfer multiple optical signals in parallel, during operation. Using a pixelated optoelectronic semiconductor device and a multicore fiber, it is possible to easily transfer multiple optical signals in parallel.

According to at least one aspect of the method for operating an optoelectronic component, each core of the multicore fiber is assigned to at most one pixel and the light emitted by the pixel is coupled into the core assigned to the pixel.

According to at least one aspect of the method for operating an optoelectronic component, the optoelectronic semiconductor device or a pixel of the optoelectronic semiconductor device has a high switching speed, during operation. The switching speed can be a measure of the rise and fall times of the optoelectronic semiconductor device. That the optoelectronic semiconductor device has a high switching speed can mean, that the active region of the optoelectronic semiconductor device comprises a high local current density.

### BRIEF DESCRIPTION OF THE DRAWINGS

Further advantages and advantageous designs and further developments of the optoelectronic semiconductor device, the optoelectronic component and the method for operating an optoelectronic component will become apparent from the following embodiments, which are described below in association with the figures.

FIG. 1 shows a cross-sectional view of a section of an optoelectronic semiconductor device according to an embodiment;

FIG. 2 shows a top view of layers of an optoelectronic semiconductor device according to an embodiment;

FIG. 3 shows a cross-sectional view of an optoelectronic semiconductor device according to a second embodiment;

FIG. 4 shows a cross-sectional view of an optoelectronic semiconductor device according to a third embodiment;

FIG. 5 shows a magnified view of a cross-section of an optoelectronic semiconductor device according to an embodiment;

FIGS. 6 to 9 show cross-sectional views of an optoelectronic semiconductor device according to embodiments; and

FIG. 10 shows a schematic view of an optoelectronic component according to an embodiment.

Identical, similar or equivalent elements are marked with the same reference signs in the figures. The figures and the proportions of the elements represented in the figures among each other are not to be considered as true to scale. Rather, individual elements may be oversized for better representability and/or comprehensibility. Identical or effectively identical components and parts might be described only with respect to the figures where they occur first. Their description is not necessarily repeated in successive figures.

### DETAILED DESCRIPTION OF ILLUSTRATIVE EMBODIMENTS

FIG. 1 shows a cross-sectional view of an optoelectronic semiconductor device 1 according to an embodiment. The optoelectronic semiconductor device 1 comprises a semiconductor layer sequence 4 with an n-type semiconductor layer 6, a p-type semiconductor layer 5 and an active region 7. The active region 7 is arranged between the p-type semiconductor layer 5 and the n-type semiconductor layer 6. The p-type semiconductor layer 5, the n-type semiconductor layer 6 and/or the active layer 7 can be based on a III-V semiconductor material, in particular on AlInGaP, GaInN and/or AlInGaAs.

The optoelectronic semiconductor device 1 comprises a p-contact 8. The p-contact 8 contacts at most 50% of an area of the p-type semiconductor layer 5. For example, the p-contact 8 contacts at most 25%, in particular at most 10%, of the p-type semiconductor layer 5.

The optoelectronic semiconductor device 1 further comprises an n-contact 9. The n-contact 9 can for example consist of or comprise an n-contact layer 9a and an n-contact via 10. The n-contact via 10 can be electrically connected with the n-contact layer 9a. The n-contact via 10 can be configured to electrically contact the n-type semiconductor layer 6. The n-contact layer 9a can be arranged on a side of the p-type semiconductor layer 5 facing away from the n-type semiconductor layer 6.

The n-contact via 10 extends from the n-contact layer 9a into the n-type semiconductor layer 6. More specifically, the n-contact via 10 extends through the p-type semiconductor layer 5 and the active region 7 into the n-type semiconductor layer 6.

Alternatively, the n-contact via 10 can be formed as an n-contact wall or an n-contact grid. This means, the n-contact via 10 can comprise a larger lateral extension along at least one lateral direction.

A light out-coupling area of the optoelectronic semiconductor device 1 may be arranged on a side of the n-type semiconductor layer 6 facing away from the active region 7.

The optoelectronic semiconductor device 1 of the embodiment shown in FIG. 1 also comprises an insulating layer 11. The insulating layer 11 is arranged between the n-contact 9, e.g. the n-contact layer 9a and/or the n-contact via 10 and the p-type semiconductor layer 5. In other words, the insulating layer 11 prevents a direct contact between the p-type semiconductor layer 5 and the n-contact 9 and/or the n-contact via 10.

The insulating layer 11 can also directly adjoin the p-type semiconductor layer 5 on a side of the p-type semiconductor layer 5 facing away from the active region 7, e.g. facing the p-contact 8. For example the insulating layer 11 directly adjoins the p-type semiconductor layer 5 in regions, in which no p-contact is in direct contact with the p-type semiconductor layer 5. For example, the p-contact 8 contacts at most 50% of an area of the p-type semiconductor layer 5. An interface between the p-contact 8 and the p-type semiconductor layer 5 is smaller than an interface between the insulating layer 11 and the p-type semiconductor layer 5.

A separation region 12 can be arranged between the n-contact layer 9a and the p-contact 8. For example, the separation region 12 extends into a solder layer 14. As shown in FIG. 1, the separation region 12 can extend through the solder layer 14 and a metallization layer 16. A region, which is arranged laterally spaced apart from the solder layer 14 and/or the metallization layer 16, can be referred to as a through-via 15. The separation region 12 can be filled with the material of the insulating layer 11. For example, the separation region 12 is completely filled with the material of the insulating layer 11. Alternatively, the separation region 12 can be filled with an insulating material, for example with air. The p-contact 8 is spaced apart from the n-contact 9 by the separation region 12 in a lateral direction. The p-contact 8 may not exceed the separation region 12 and/or may not overlap with the n-contact 9.

The optoelectronic semiconductor device 1 further comprises a carrier 18, on which the semiconductor layer sequence 4 is arranged. A plurality of switches 17 can be integrated into the carrier 18. Each through-via 15 and/or each p-contact 8 can be associated with a switch 17. Insulating regions 27, which isolate the p-contacts 8 from each other are arranged on a side of the carrier 18 facing the semiconductor layer sequence 4. The carrier 18 can comprise feed lines 28, via which the pixels 3 of the optoelectronic semiconductor device 1 can be driven via an electrical control circuit.

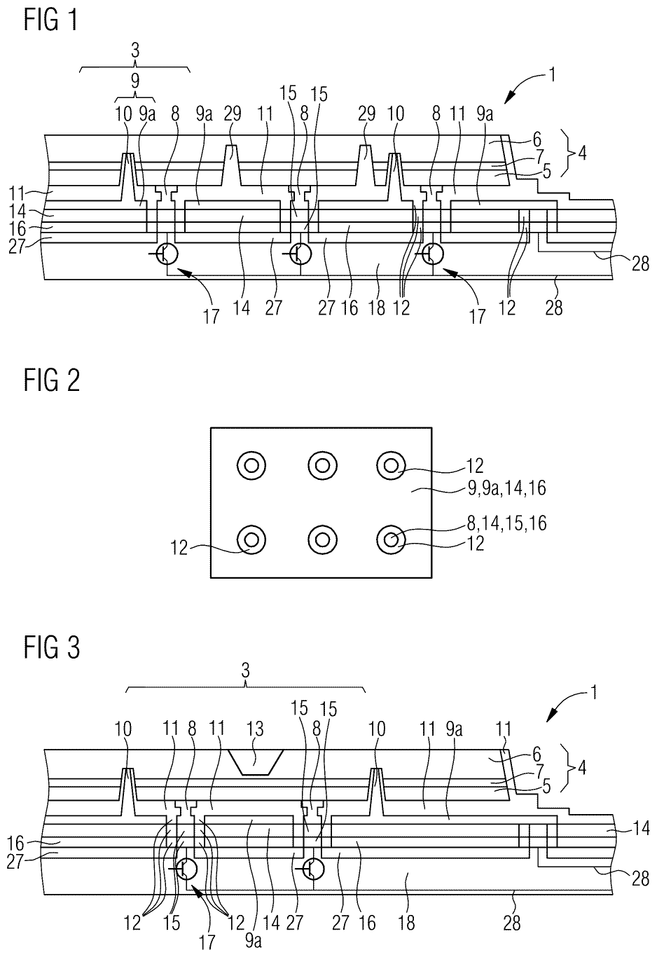

FIG. 2 shows a top view of layers of an optoelectronic semiconductor device 1 according to an embodiment. For example, FIG. 2 shows a top view of the solder layer 14, the n-contact layer 9a or the metallization 16. A separation region 12 separates the through-via 15 from the remaining parts of the layer. For example, the separation region 12 has the shape of a ring, in top view. The p-contact 8 is spaced apart from the n-contact layer 9a by the separation region 12, for example.

FIG. 3 shows a cross-sectional view of an optoelectronic semiconductor device 1 according to a second embodiment. The optoelectronic semiconductor device 1 shown in FIG. 3 differs from the optoelectronic semiconductor device 1 shown in FIG. 1 in that the n-type semiconductor layer 6 comprises a recess 13, for example. The recess 13 extends from a side of the n-type semiconductor layer 6 facing away from the active region 7 towards the active region 7. The recess 13 does not extend into the active region 7. For example, the recess 13 is filled with an insulating material. The recess 13 can be filled with a transparent material. The recess 13 can be configured to increase the local current density, e.g. by blocking or by limiting a current spreading inside the n-type semiconductor layer 6.

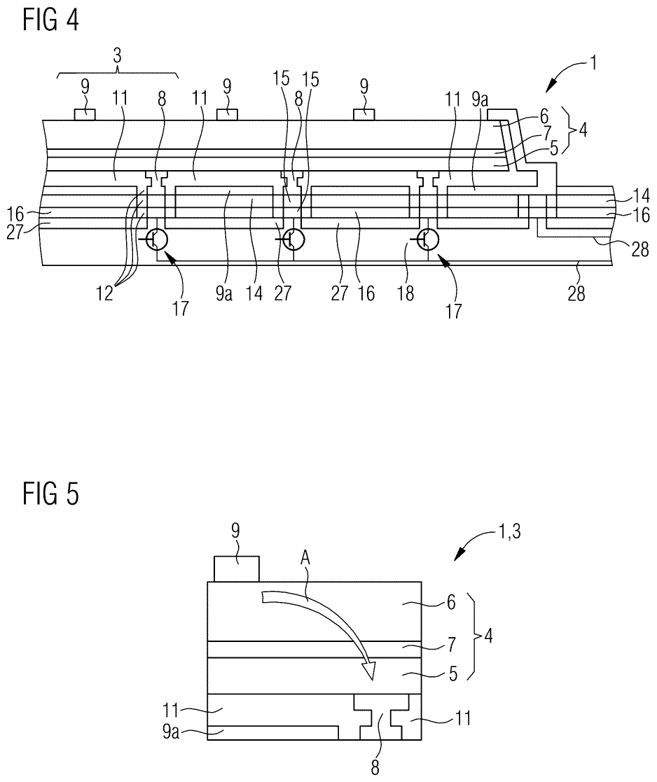

FIG. 4 shows a cross-sectional view of an optoelectronic semiconductor device 1 according to a third embodiment. The optoelectronic semiconductor device 1 shown in FIG. 4 differs from the optoelectronic semiconductor device 1 shown in FIG. 2, in that the n-contact 9 is arranged on a side of the n-type semiconductor layer 6 facing away from the p-type semiconductor layer 5. The n-contact 9 is not formed as an n-contact via. For example, the n-contact 9 is formed as an n-contact grid.

FIG. 5 shows a magnified view of a cross-section of an optoelectronic semiconductor device 1 according to an embodiment, for example of the embodiment shown in FIG. 4. The arrow A indicates the flowing of the current from the n-contact 9 to the p-contact 8 within the semiconductor layer sequence 4. The current is distributed non-uniformly within the pixel. A high local current density can be achieved in the active region 7 of the optoelectronic semiconductor device 1.

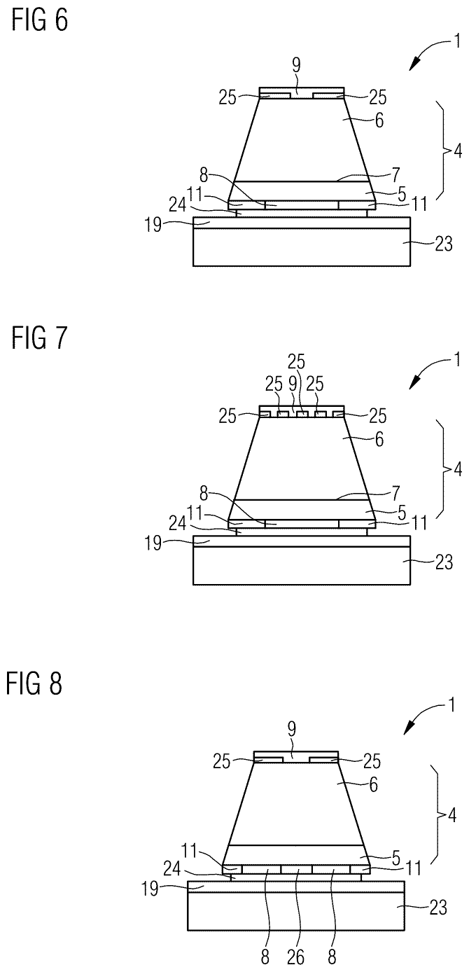

FIG. 6 shows a cross-sectional view of an optoelectronic semiconductor device 1 according to an embodiment. The optoelectronic semiconductor device 1 comprises a semiconductor layer sequence 4 with a p-type semiconductor layer 5, an n-type semiconductor layer 6 and an active region 7, which is arranged between the p-type semiconductor layer 5 and the n-type semiconductor layer 6. The p-type semiconductor layer 5, the n-type semiconductor layer 6 and/or the active region 7 can be based on a III-V semiconductor material, in particular on AlInGaP, GaInN and/or AlInGaAs.

The active region 7 is configured for generating and/or emitting electromagnetic radiation. The optoelectronic semiconductor device 1 can emit the electromagnetic radiation generated by the active region 7. For example, the active region 7 emits visible light, UV radiation and/or IR radiation. The active region 7 can comprise a pn-junction, a quantum well and/or a multi-quantum well, for example.

The optoelectronic semiconductor device 1 also comprises a p-contact 8. The p-contact 8 is arranged on a side of the p-type semiconductor layer 5 facing away from the active region 7. The p-contact 8 is directly adjacent to the p-type semiconductor layer 5. The p-contact 8 contacts at most 50%, for example at most 30% or in particular at most 10% of an area of the p-type semiconductor layer 5. The area of the p-type semiconductor layer 5 can be the area of the p-type semiconductor layer 5 on the side of the p-type semiconductor layer 5 facing the p-contact 8. The p-contact 8 can be directly adjacent to the area of the p-type semiconductor layer 5, which is contacted at most 50% by the p-contact 8. In other words, the p-contact 8 can be directly adjacent to at most 50%, for example at most 30% or in particular at most 10% of the side of the p-type semiconductor layer 5 facing away from the n-type semiconductor layer 6. For example, a lateral extension and/or a diameter of the p-contact 8 is at most 1 μm, for example at most 500 nm.

For example, electrical current is injected into the p-type semiconductor layer 5 by the p-contact 8. The p-contact 8 can comprise or can be formed of a metal and/or a transparent conductive oxide (TCO). For example, the p-contact 8 can be the only part of the optoelectronic semiconductor device 1 injecting current into the p-type semiconductor layer 5.

An insulating layer 11 of the optoelectronic semiconductor device 1 can be arranged on a side of the p-type semiconductor layer 5 facing away from the n-type semiconductor layer 6. For example, the insulating layer 11 is a p-side insulating layer 11 and can be arranged on the side of the p-type semiconductor layer 5 facing the p-contact 8. The insulating layer 11 can comprise an electrically insulating material. For example, the insulating layer 11 is electrically insulating. The insulating layer 11 may comprise an electrically insulating oxide and/or nitride and/or a dielectric material or may be formed of an electrically insulating oxide and/or nitride and/or dielectric material. For example, the insulating layer 11 comprises SiO₂ or is formed of SiO₂.

The insulating layer 11 can directly adjoin the p-contact 8. For example, the insulating layer 11 laterally surrounds the p-contact 8 at least partially. In particular, the insulating layer 11 laterally surrounds the p-contact 8 completely. The insulating layer 11 can cover the parts of the side of the p-type semiconductor layer 5 facing away from the n-type semiconductor layer 6 which are not covered by the p-contact 8 at least partially or completely.

The optoelectronic semiconductor device 1 shown in FIG. 6 comprises an n-contact 9. The n-contact 9 can comprise a transparent conductive oxide (TCO) or can be comprised of a TCO. The n-contact 9 is arranged on a side of the n-type semiconductor layer 6 facing away from the p-type semiconductor layer 5. The n-contact 9 can be in direct contact with the n-type semiconductor layer 6. The n-contact 9 can form a common interface with the n-type semiconductor layer 6. For example, the n-contact 9 is configured to inject current, in particular electrical current, into the n-type semiconductor layer 6.

An n-side insulating layer 25 can be arranged on a side of the n-type semiconductor layer 6 facing away from the p-type semiconductor layer 5. The n-side insulating layer 25 can be directly adjacent to the n-contact 9 and the n-type semiconductor layer 6. For example, the n-side insulating layer 25 can be partially arranged between the n-contact 9 and the n-type semiconductor layer 6. The shape and/or the size of a contact area in which the n-contact 9 contacts the n-type semiconductor layer 6 can be defined by the n-side insulating layer 25. Preferably, the n-side insulating layer 25 is transparent, in particular transparent for the electromagnetic radiation or the optical signal generated by the active region 7 of the optoelectronic semiconductor device 1.

For example, the n-contact 9 contacts the n-type semiconductor layer 6 approximately in the middle of the n-type semiconductor layer 6. Then, the n-side insulating layer 25 can be arranged to at least partially surround the n-contact 9 at least partially in a lateral direction. The n-side insulating layer 25 can completely surround the n-contact 9 in the lateral direction.

The optoelectronic semiconductor device 1 can comprise a p-contact pad 24. The p-contact pad 24 can be arranged on a side of the p-contact 8 and/or on a side of the insulating layer 11 facing away from the p-type semiconductor layer 5. In other words, the p-contact 8 can be arranged between the p-contact pad 24 and the p-type semiconductor layer 5. For example, the p-contact pad 24 is at least partially in direct contact with the p-contact 8.

For example, as shown in FIG. 6, the optoelectronic semiconductor device 1 is arranged on a temporary carrier 23. The optoelectronic semiconductor device 1 can be attached to the temporary carrier 23 via an adhesive layer 19. That the optoelectronic semiconductor device 1 is arranged on the temporary carrier 23 can mean that the optoelectronic semiconductor device 1 can be detached from the temporary carrier 23 and may be attached to another carrier. In particular, the optoelectronic semiconductor device 1 can be detached from the temporary carrier 23 non-destructively.

FIG. 7 shows a cross-sectional view of an optoelectronic semiconductor device 1 according to an embodiment. The optoelectronic semiconductor device 1 shown in FIG. 7 differs from the embodiment of the optoelectronic semiconductor device 1 shown in FIG. 6 in that the n-contact 9 is structured, for example. For example, the n-contact 9 contacts at least two areas of the n-type semiconductor layer 6, which are arranged spaced apart from one another in a lateral direction on a surface of the n-type semiconductor layer 6 facing away from the active region 7. The structures of the n-contact 9 can be connected with each other.

In the cross-section of the optoelectronic semiconductor device 1 shown in FIG. 7, the n-contact 9 resembles a comb. The comb teeth can be in direct contact with the n-type semiconductor layer 6. For example, the n-side insulating layer 25 is arranged between the structures of the n-contact 9 in a lateral direction. It is possible, that the n-side insulating layer 25 and the n-contact 9 are arranged as alternating circles or rectangles in top view.

FIG. 8 shows a cross-sectional view of an optoelectronic semiconductor device 1 according to an embodiment. The optoelectronic semiconductor device 1 of the embodiment shown in FIG. 8 differs from the embodiment of the optoelectronic semiconductor device 1 shown in FIG. 6 in that a further insulating layer 26 is arranged on a side of the p-type semiconductor layer 5 facing away from the n-type semiconductor layer 6.

The further insulating layer 26 can be in direct contact with the p-type semiconductor layer 5. For example, the further insulating layer 26 is at least partially laterally surrounded by the p-contact 8 and/or by the insulating layer 11. The further insulating layer 26 can be configured to structure the p-contact 8. This embodiment may be combined with the structured n-contact described in combination with the embodiment shown in FIG. 7. A structured p-contact 8 may be also applied in the embodiments of the optoelectronic semiconductor devices shown in FIGS. 6, 7 and 9.

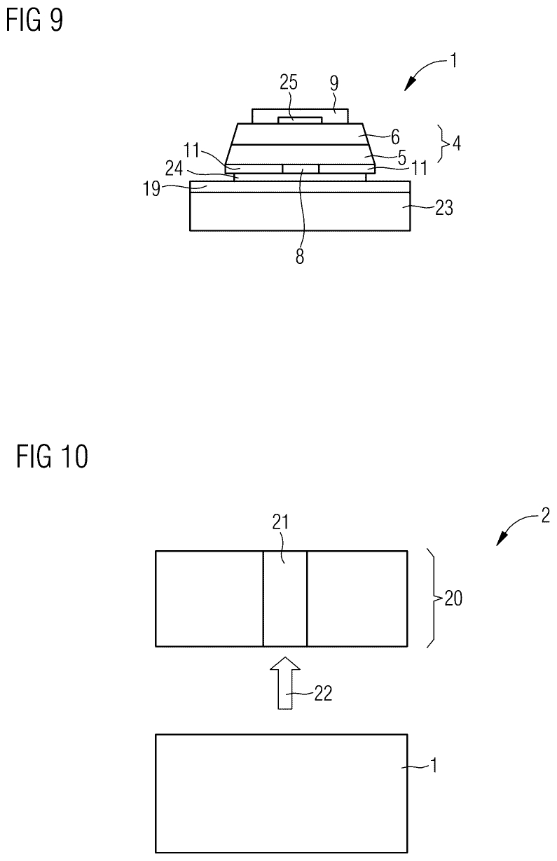

FIG. 9 shows a cross-sectional view of an optoelectronic semiconductor device 1 according to an embodiment. The optoelectronic semiconductor device 1 shown in FIG. 9 differs from the embodiment of the optoelectronic semiconductor device 1 shown in FIG. 6 in that the n-side insulating layer 25 is arranged approximately in the middle of the surface of the n-type semiconductor layer 6 facing away from the p-type semiconductor layer 5. The n-contact 9 can laterally surround the n-side insulating layer 25 partially. For example, the n-contact 9 completely surrounds the n-side insulating layer 25 laterally and/or covers a side of the insulating layer facing away from the n-type semiconductor layer 6 partially or completely. In the embodiment of FIG. 9, the thickness of the n-type semiconductor layer 6 is decreased. The thickness is the extension of the n-type semiconductor layer 6 along the stacking direction of the semiconductor layer sequence 4. For example, the thickness of the n-type semiconductor layer 6 is at most 1 μm, for example at most 500nm or at most 200 nm. The thickness of the n-type semiconductor layer 6 can be at least 50 nm, for example at least 100 nm.

FIG. 10 shows a schematic view of an optoelectronic component 2 according to an embodiment. The optoelectronic component 2 comprises an optoelectronic semiconductor device 1 and an optical fiber 20. The optoelectronic semiconductor device 1 is configured to emit electromagnetic radiation, for example an optical signal 22, and the optical fiber 20 is configured to transfer the light emitted by the optoelectronic semiconductor device.

The optical fiber 20 can be a multicore or an imaging fiber, and each pixel 3 of the optoelectronic semiconductor device 1 is assigned one core 21 of the optical fiber 20. During operation of the optoelectronic component 2, the electromagnetic radiation, e.g. the optical signal 22 emitted by the optoelectronic semiconductor device 1 is coupled into the optical fiber 20. In case the optical fiber 20 is a multicore fiber, the optical fiber 20 can be configured to transfer multiple optical signals 22 provided by the pixels 3 of the optoelectronic semiconductor device 1 in parallel. For example, each core 21 of the multicore fiber can be assigned to at most one pixel 3 of the optoelectronic component 2. The electromagnetic radiation emitted by the pixel 3 can be coupled into the core 21 of the optical fiber 20 assigned to the pixel 3.

The invention described herein is not limited by the description given with reference to the embodiments. Rather, the invention encompasses any novel feature and any combination of features, including in particular any combination of features in the claims, even if this feature or this combination is not itself explicitly indicated in the claims or embodiments.

1.-19. (canceled)

20. An optoelectronic semiconductor device comprising:
a p-type semiconductor layer;
an n-type semiconductor layer;
an active region arranged between the p-type semiconductor layer and the n-type semiconductor layer;
a p-contact contacting at most 50% of an area of the p-type semiconductor layer; and
an n-contact arranged on a side of the n-type semiconductor layer facing away from the p-type semiconductor layer,
wherein the p-contact is arranged on a side of the p-type semiconductor layer facing away from the active region.

21. The optoelectronic semiconductor device according to claim 20, wherein the p-contact contacts at most 25% of the p-type semiconductor layer.

22. The optoelectronic semiconductor device according to claim 20, wherein the p-type semiconductor layer, the n-type semiconductor layer and/or the active region are based on a III-V semiconductor material.

23. The optoelectronic semiconductor device according to claim 20, further comprising:
an insulating layer directly adjacent to the p-type semiconductor layer on a side of the p-type semiconductor layer facing away from the active region,
wherein an interface between the p-contact and the p-type semiconductor layer is smaller than an interface between the insulating layer and the p-type semiconductor layer.

24. The optoelectronic semiconductor device according to claim 20, wherein the p-contact is spaced apart from the n-contact by a separation region in a lateral direction, and wherein the p-contact does not overlap the n-contact.

25. The optoelectronic semiconductor device according to claim 20, wherein the n-contact comprises an n-contact layer arranged over the entire surface of the optoelectronic semiconductor device below the p-contact, and wherein the p-contact is surrounded laterally by the n-contact layer in top view.

26. The optoelectronic semiconductor device according to claim 20, wherein the n-contact comprises an n-contact layer and n-contact vias, which reach through a plane in which the p-contact is arranged.

27. The optoelectronic semiconductor device according to claim 26, further comprising a plurality of pixels, wherein a number of n-contact vias is smaller than a number of pixels.

28. The optoelectronic semiconductor device according to claim 20, wherein the n-contact is arranged along a side surface of the semiconductor layers to a side of the n-type semiconductor layer facing away from the active region and covers the n-type semiconductor layer as a contact grid.

29. The optoelectronic semiconductor device according to claim 20, further comprising a plurality of pixels, each pixel comprising exactly one p-contact.

30. The optoelectronic semiconductor device according to claim 29, wherein at least two pixels of the plurality of pixels comprise a common and continuous active region or arise from a common active zone.

31. The optoelectronic semiconductor device according to claim 20,
wherein the n-type semiconductor layer comprises a recess, and
wherein the recess extends from a side of the n-type semiconductor layer facing away from the active region towards the active region,
wherein the recess does not extend into the active region, and
wherein the recess is at least partially filled with an insulating material.

32. The optoelectronic semiconductor device according to claim 20, wherein the optoelectronic semiconductor device comprises a micro-LED or is a micro-LED.

33. The optoelectronic semiconductor device according to claim 20, wherein the optoelectronic semiconductor device comprises a plurality of pixels and the pixels are formed by micro-LEDs.

34. The optoelectronic semiconductor device according to claim 20, wherein the optoelectronic semiconductor device is configured to emit electromagnetic radiation and is configured for optical data communication.

35. An optoelectronic component comprising:
an optoelectronic semiconductor device comprising:
a p-type semiconductor layer;
an n-type semiconductor layer;
an active region arranged between the p-type semiconductor layer and the n-type semiconductor layer; and
a p-contact contacting at most 50% of an area of the p-type semiconductor layer; and
an optical fiber,
wherein the optoelectronic semiconductor device is configured to emit electromagnetic radiation, and
wherein the optical fiber is configured to transfer the electromagnetic radiation emitted by the optoelectronic semiconductor device.

36. The optoelectronic component according to claim 35, wherein the optical fiber is a multicore fiber, and wherein each pixel of the optoelectronic semiconductor device is assigned one core of the optical fiber.

37. A method for operating the optoelectronic component according to claim 35, the method comprising:
coupling light emitted by the optoelectronic semiconductor device into the optical fiber.

38. The method according to claim 37,
wherein the optical fiber is a multicore fiber,
wherein each pixel of the optoelectronic semiconductor device is assigned a core of the multicore fiber, and
wherein the optical fiber transfers multiple optical signals in parallel.
